(19) United States
(12) Patent Application Publication
(10) Pub. No.: US 2024/0282672 A1
(43) Pub. Date: Aug. 22, 2024

(54) SEMICONDUCTOR DEVICE INCLUDING A THREE-DIMENSIONAL INTEGRATED CIRCUIT

(71) Applicant: SAMSUNG ELECTRONICS CO., LTD., Suwon-si (KR)

(72) Inventors: BONGWEE YU, Suwon-si (KR); KYOUNG -MIN LEE, Suwon-si (KR); KYUNGSOO LEE, Suwon-si (KR); JUNHO HUH, Suwon-si (KR)

(21) Appl. No.: 18/389,251

(22) Filed: Nov. 14, 2023

(30) Foreign Application Priority Data
Feb. 21, 2023 (KR) 10-2023-0023037

(51) Int. Cl. H01L 23/48; H01L 23/00; H01L 23/528; H01L 25/10; H10B 80/00

(52) U.S. Cl. CPC H01L 23/481; H01L 23/528; H01L 24/16; H01L 25/105; H10B 80/00; H01L 24/14; H01L 2224/14181; H01L 2224/16145; H01L 2224/16225

(57) ABSTRACT

A semiconductor device includes: a package substrate; a first die on the package substrate and including a hard macro and through silicon vias; and a second die on the first die, wherein the first die includes a first region, which does not include the hard macro, and a second region including a macro-region that includes the hard macro, wherein the through silicon vias of the first region are arranged in a first direction with a first distance and in a second direction with a second distance, wherein the through silicon vias of the second region are arranged in the first direction with a first pitch, and in the second direction with a second pitch, wherein the macro-region is interposed between the through silicon vias arranged in the first direction, wherein the first pitch is greater than the first distance, and wherein the second pitch is less than the second distance.

### CROSS-REFERENCE TO RELATED APPLICATION

This application claims priority under 35 U.S.C. § 119 to Korean Patent Application No. 10-2023-0023037 filed on Feb. 21, 2023, in the Korean Intellectual Property Office, the disclosure of which is incorporated by reference herein in its entirety.

### TECHNICAL FIELD

Embodiments of the present inventive concept described herein relate to a semiconductor device, and more particularly, to a semiconductor device including a three-dimensional integrated circuit.

### DISCUSSION OF RELATED ART

Recently, System In Package (SIP), which typically is to mount a plurality of semiconductor devices in one package, has been under development. To reduce the occupied area of semiconductor devices in the package and make high-speed communication between the semiconductor devices, a three-dimensional semiconductor device formed by vertically stacking the plurality of semiconductor devices using through silicon via (TSV) has been under development.

### SUMMARY

According to an embodiment of the present inventive concept, a semiconductor device includes: a package substrate; a first die provided on the package substrate and including a hard macro and a plurality of through silicon vias; and a second die provided on the first die and electrically connected to the plurality of through silicon vias, wherein the first die includes a first region, in which the hard macro is not disposed, and a second region including a macro-region in which the hard macro is disposed, wherein the plurality of through silicon vias of the first region are arranged in a first direction with a first distance therebetween and in a second direction with a second distance therebetween, wherein the second direction crosses the first direction, wherein the plurality of through silicon vias of the second region are arranged in the first direction with a first pitch, and in the second direction with a second pitch, wherein the macro-region is interposed between the plurality of through silicon vias that are arranged in the first direction in the second region, wherein the first pitch is greater than the first distance, and wherein the second pitch is less than the second distance.

According to an embodiment of the present inventive concept, a semiconductor device includes: a package substrate; a first die provided on the package substrate and including a hard macro and a plurality of through silicon vias; and a second die provided on the first die and electrically connected to the plurality of through silicon vias, wherein the first die includes a first region, in which the hard macro is not disposed, a second region including a macro-region, in which the hard macro is disposed, and through silicon via groups including the plurality of through silicon vias, wherein the plurality of through silicon vias of the first region are arranged in a first direction with a first distance therebetween, and in a second direction with a second distance therebetween, wherein the second direction crosses the first direction, wherein the through silicon via groups are arranged to be spaced apart from each other in the first direction and the second direction in the second region, wherein the macro-region is interposed between the through silicon via groups in the first direction and between the through silicon via groups in the second direction, and wherein each of the through silicon via groups includes a first plurality of through silicon vias, of the plurality of through silicon vias, arranged in the first direction.

According to an embodiment of the present inventive concept, a semiconductor device includes: a package substrate; a first die provided on the package substrate and including a substrate and an active layer; a rear wire layer provided on the first die and including a ground wire; and a second die provided on the rear wire layer, wherein the active layer includes first through silicon via groups, second through silicon via groups, and a macro-region, wherein the first through silicon via groups include through silicon vias configured to supply a power supply voltage to the second die, wherein the second through silicon via groups include ground through silicon vias configured to supply a ground voltage to the second die, and wherein a hard macro is disposed in the macro-region, wherein the macro-region is interposed between the first through silicon via groups, and wherein the ground wire is electrically connected to the ground through silicon vias.

### BRIEF DESCRIPTION OF THE FIGURES

The above and other objects and features of the present inventive concept will become apparent by describing in detail embodiments thereof with reference to the accompanying drawings, in which:

FIG. 1 is a view illustrating a conventional semiconductor device compared to an embodiment of the present inventive concept.

FIG. 2 is a plan view illustrating a first die of FIG. 1.

FIG. 3 is an enlarged view illustrating a second region of FIG. 2.

FIG. 4 is a view illustrating a semiconductor device according to an embodiment of the present inventive concept.

FIG. 5 is a plan view illustrating a first die of FIG. 4.

FIG. 6 is an enlarged view illustrating a second region of FIG. 5.

FIG. 7 is a view illustrating a second region of FIG. 5 according to an embodiment of the present inventive concept.

FIG. 8 is a view illustrating an SRAM disposed in a macro-region of FIG. 7.

FIG. 9 is a view illustrating a second region of FIG. 5 according to an embodiment of the present inventive concept.

FIG. 10 is a view illustrating a semiconductor device according to an embodiment of the present inventive concept.

FIG. 11 is a plan view illustrating a first die of FIG. 10.

FIG. 12 is a view illustrating a semiconductor device according to an embodiment of the present inventive concept.

### DETAILED DESCRIPTION

Hereinafter, embodiments of the present inventive concept will be described more fully with reference to the accompanying drawings, in which embodiments are shown.

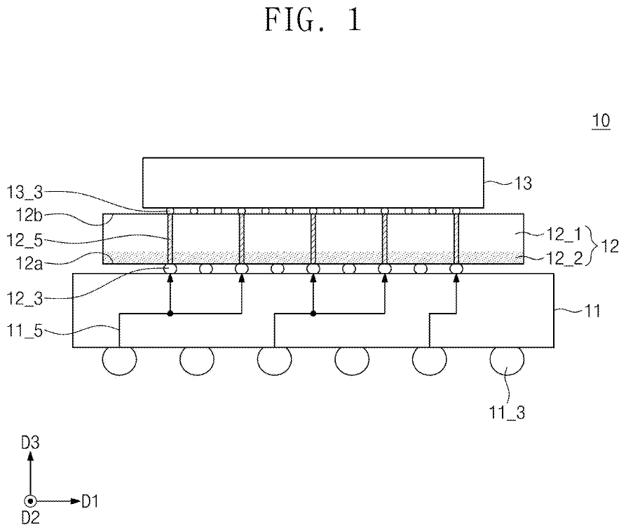

FIG. 1 is a view illustrating a semiconductor device according to a comparative example. Hereinafter, a conventional semiconductor device will be described in detail with reference to FIG. 1.

Referring to FIG. 1, a semiconductor device 10 may include a package substrate 11, a first die 12, and a second die 13. The first die 12 and the second die 13 may be mounted on the package substrate 11. For example, the semiconductor device 10 may be a three-dimensional integrated circuit (3DIC).

The package substrate 11 may be a printed circuit board. The package substrate 11 may be formed in a first direction D1 and a second direction D2. The first direction D1 and the second direction D2 may be substantially perpendicular to each other.

An external terminal 11_3 may be provided on a bottom surface of the package substrate 11. The bottom surface of the package substrate 11 may indicate one surface of the package substrate 11, which faces a direction opposite to the third direction D3. The third direction D3 may be a direction D3 substantially perpendicular to a plane formed by the first direction D1 and the second direction D2. A plurality of external terminals 113 may be provided.

The package substrate 11 may be configured to receive various signals through the external terminals 11_3. For example, the package substrate 11 may receive a power signal to drive the semiconductor device 10 through at least some of the external terminals 11_3.

The package substrate 11 may include inner wires 11_5. Various signals received from the external terminal 11_3 may be transmitted to the first die 12 and the second die 13 through the inner wires 11_5 that are located in the package substrate 11.

The first die 12 and the second die 13 may be provided on a top surface of the package substrate 11. For example, the first die 12 may be provided on the package substrate 11, and the second die 13 may be provided on the first die 12. In other words, the first die 12 and the second die 13 may be sequentially provided on the package substrate 11 in the third direction D3 substantially perpendicular to the plane formed by the first direction D1 and the second direction D2.

The first die 12 may be a processor chip. For example, the first die 12 may include a central processing unit (CPU), a graphic processing unit (GPU), or a system on chip (SoC).

The first die 12 may have a first surface 12a facing the package substrate 11 and a second surface 12b opposite to the first surface 12a. The first die 12 may include a substrate 12_1 and an active layer 12_2. The active layer 12_2 may be adjacent to the first surface 12a. The substrate 121 may be adjacent to the second surface 12b. During the process of mounting the first die 12 on the package substrate 11, the first die 12 may be mounted on the package substrate 11 while the second surface 12b of the first die 12 faces down.

The active layer 12_2 of the first die 12 may include hard macros. The hard macro may include various intellective properties (LP). For example, IP may refer to implemented and reusable blocks in a fixed layout and interconnection specified to perform a desired electrical function. According to an embodiment of the present inventive concept, the hard macro may be a static random access memory (SRAM). However, the scope of the present inventive concept is not limited thereto, and the hard macro may include various electronic circuits or functional blocks such as Phase Locked Loop (PLL), Analog to Digital Converter (ADC), Digital to Analog Converter (DAC), or memory block.

The first die 12 may include through silicon via 12_5. The through silicon via 12_5 may electrically connect the package substrate 11 with the second die 13. For example, the through silicon via 12_5 may be configured to apply a power signal, which is for driving the second die 13, from the package substrate 11 to the second die 13.

According to one embodiment of the present inventive concept, a power supply voltage may be supplied from the package substrate 11 to the second die 13 through at least some of the through silicon vias 12_5, and a ground voltage may be supplied from the package substrate 11 to the second die 13 through at least others of the through silicon vias 12_5.

The through silicon vias 12_5 may be formed to be spaced apart from each other by a specific distance inside the first die 12. The distance between the through silicon vias 12_5 may be determined or designed based on a voltage drop (IR-Drop) phenomenon occurring in the second die 13.

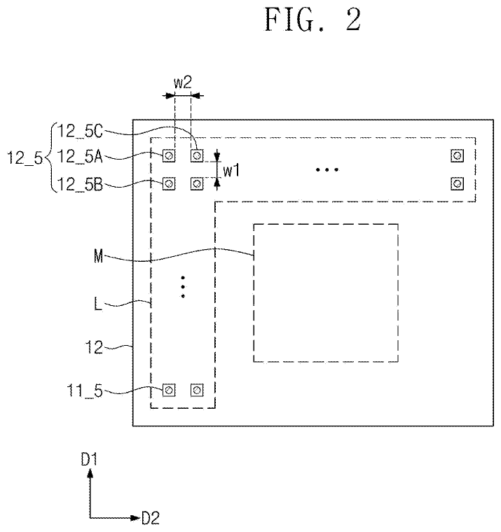

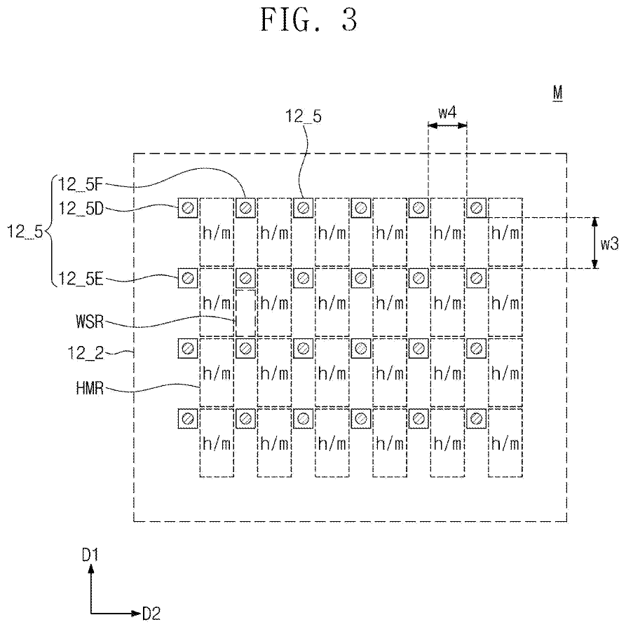

The through silicon via 12_5 may extend in the third direction D3 through the first die 12. According to an embodiment of the present inventive concept, the through silicon vias 12_5 inside the first die 12 might not pass through the hard macros of the first die 12. In other words, the hard macros may be disposed in a region in which the through silicon vias 12_5 are not provided inside the first die 12. The detailed arrangement relationship between the through silicon via 12_5 and the hard macros in the first die 12 will be described later with reference to FIGS. 2 and 3.

Connection bumps 123 may be interposed between the package substrate 11 and the first die 12. The connection bumps 12_3 may be, for example, controlled collision chip connection C4 bumps. Some of the connection bumps 12_3 may be electrically connected to the first die 12. The first die 12 may be configured to receive various signals from the package substrate 11 through the connection bumps 12_3. Another portion of the connection bumps 12_3 may be electrically connected to the through silicon vias 12_5. Some connection bumps 12_3 might not be electrically connected to the through silicon vias 12_5.

Micro-bumps 13_3 may be provided between the first die 12 and the second die 13. The micro-bumps 13_3 may be electrically connected to the through silicon via 12_5 passing through the first die 12. Some micro-bumps 13_3 might not be electrically connected to the through silicon via 12_5. The second die 13 may receive various signals through the micro-bumps 133. For example, the second die 13 may receive power signals for driving the second die 13 through the connection bumps 12_3, the through silicon via 12_5, and the micro-bumps 13_3.

FIG. 2 is a plan view illustrating the first die of FIG. 1. FIG. 3 is an enlarged view illustrating a second region of FIG. 2.

Referring to FIGS. 2 and 3, the first die 12 may include a first region L, in which the hard macro is not disposed, and a second region M, in which the hard macro is disposed.

The plurality of through silicon via 125 may be disposed in the first region L of the first die 12. In the first region L, the through silicon vias 12_5 may be arranged in the first direction D1 and the second direction D2. For example, the through silicon vias 12_5 may be uniformly arranged in a matrix form. However, the arrangement of the through silicon vias 205 is not limited to what is illustrated in FIG. 2. For example, the through silicon vias 125 may be arranged in a zigzag form, an alternating arrangement, or in various other regular forms. In addition, the through silicon vias 12_5 may be irregularly arranged.

In the first region L, the through silicon vias 12_5 may be spaced apart from each other by a specific distance. For example, the through silicon vias 12_5 may include first to third through silicon via 12_5A, 12_5B, and 12_5C. The first through silicon via 12_5A may be closest to the second through silicon via 12_5B in the first direction D1, in comparison to other through silicon vias 12_5. In this case, the first through silicon via 12_5A and the second through silicon via 12_5B may be spaced apart from each other by a first distance w1. In addition, the first through silicon via 12_5A may be closest to the third through silicon via 12_5C in the second direction D2, in comparison to other through silicon vias 12_5. In this case, the first through silicon via 12_5A and the third through silicon via 12_5C may be spaced apart from each other by a second distance w2. For example, hard macros may be disposed in a region between the through silicon vias 12_5.

Referring to FIG. 3, macro-regions HMR and a plurality of through silicon vias 12_5 may be disposed in the second region M of the first die 12. Hard macros may be disposed in each of the macro-regions HMR. The macro-region HMR may have the shape of a rectangle. However, the present inventive concept is not limited thereto. For example, the macro-region HMR may have a polygonal shape, other than a rectangle, or a circular shape.

In the second region M, the through silicon vias 125 may be spaced apart from each other by a specific distance. For example, the through silicon via 125 may be spaced apart from each other at regular intervals in the first direction D1. For example, the through silicon vias 125 may be spaced apart from each other at regular intervals in the second direction D2.

For example, the through silicon vias 12_5 may include fourth to sixth through silicon vias 12_5D, 12_5E, and 12_5F. The fourth through silicon via 12_5D may be closest to the second through silicon via 12_5E in the first direction D1, in comparison to other through silicon vias 12_5. In this case, the fourth and fifth through silicon vias 12_5D and 12_5E may be spaced apart from each other by a third distance w3. In addition, the fourth through silicon via 12_5D may be closest to the sixth through silicon via 12_5F in the second direction D2, in comparison to other through silicon vias 125. In this case, the fourth and sixth through silicon via 12_5D and 12_5F may be spaced apart from each other by a fourth distance w4.

The macro-regions HMR may be disposed adjacent to the through silicon vias 12_5. For example, a portion of the macro-region HMR may be disposed between the through silicon vias 12_5 that are spaced apart from each other in the second direction D2. For example, the portion of the macro-region HMR may be interposed between the fourth through silicon via 12_5D and the sixth through silicon via 12_5F in the second direction D2.

For example, empty regions WSR may be provided between the through silicon via 12_5 spaced apart from each other in the first direction D1. The empty region WSR may be a region in which the hard macro is not provided. The size of the semiconductor device may be increased due to the empty regions WSR between the through silicon vias 12_5 spaced apart from each other in the first direction D1, and the manufacturing yield of the semiconductor device may be decreased.

According to some embodiments of the present inventive concept, the through silicon vias 12_5 may be arranged to supply a power signal to alleviate voltage drop occurring in the second die 13 while reducing the macro-region HMR and the empty regions WSR around through regions, in which through silicon vias 12_5 may be provided. Hereinafter, embodiments according to the present inventive concept will be described in detail.

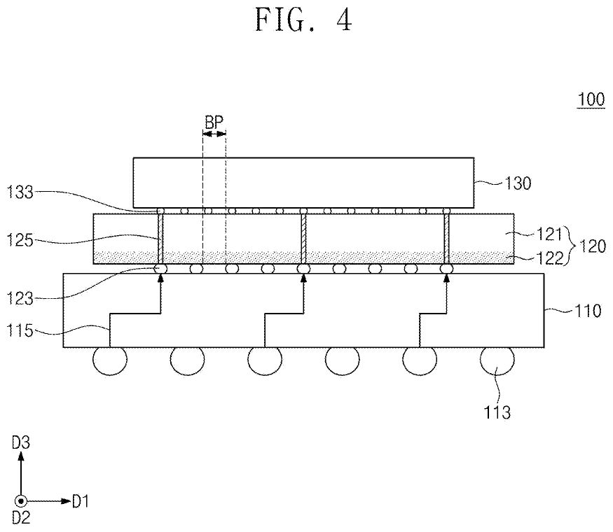

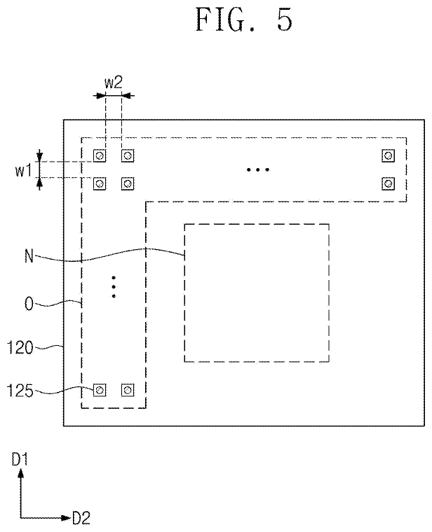

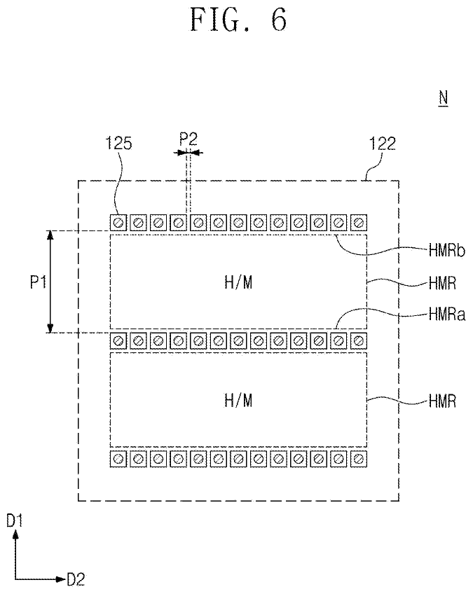

FIG. 4 is a view illustrating a semiconductor device according to an embodiment of the present of the present inventive concept. FIG. 5 is a plan view illustrating the first die of FIG. 4. FIG. 6 is an enlarged view illustrating a second region of FIG. 5.

Referring to FIGS. 4 to 6, according to an embodiment of the present inventive concept, the semiconductor device 100 may include the package substrate 110, the first die 120, and the second die 130. The connection bumps 123 may be interposed between the package substrate 110 and the first die 120, and the micro-bumps 133 may be interposed between the first die 120 and the second die 130. The first die 120 may include the substrate 121 and the active layer 122, and the active layer 122 may include the plurality of through silicon vias 125 and the hard macro.

The first die 120 may include a first region O in which the hard macro is not disposed and a second region N in which the hard macro is disposed.

The plurality of through silicon vias 125 may be disposed in the first region O of the first die 120. In the first region O, the through silicon vias 125 may be arranged in the first direction D1 and the second direction D2. For example, the through silicon vias 125 may be uniformly arranged in the form of a matrix. However, the present inventive concept is not limited thereto.

The through silicon vias 125 may be spaced apart from each other by a specific distance. In the first region O, the through silicon vias 125 closet to each other in the first direction D1 may be spaced apart from each other by the first distance w1. In the first region O, the through silicon vias 125 closest to each other in the second direction D2 may be spaced apart from each other by a second distance w2.

Referring to FIG. 6, a plurality of through silicon via 125 and the macro-regions HMR may be disposed in the second region N of the first die 120.

The through silicon vias 125 in the second region N may be arranged in the second direction D2. For example, the through silicon vias 125 in the second region N may be arranged in the form of a line in the second direction D2. In this specification, the arrangement of the through silicon vias 125 in the form of a line may be that the through silicon vias 125 are arranged in a line at regular intervals. However, the present inventive concept is not limited thereto, and for example, the through silicon vias 125 may be arranged in the second direction D2 with an alternating or zigzagging arrangement.

The through silicon vias 125 in the second region N may be arranged to have a specific distance therebetween in the second direction D2. For example, the minimum distance between the through silicon vias 125 in the second direction D2 may be a second pitch P2. The second pitch P2 may be in the range of about 1 μm to about 10 μm. The macro-region HMR might not be interposed between the through silicon vias 125 that are arranged in the second direction D2.

The through silicon vias 125 in the second region N may be spaced apart from each other at a specific interval in the first direction D1. For example, the minimum distance between the through silicon vias 125 in the first direction D1 may be the first pitch P1. The first pitch P1 may be in the range of about 100 μm to about 200 μm.

The macro-region HMR may be interposed between the through silicon via 125 spaced apart from each other in the first direction D1. The macro-region HMR may extend in the second direction D2. The plurality of through silicon vias 125 may be disposed along a first lateral side HMRa and a second lateral side HMRb facing the first lateral side HMRa in the macro-region HMR. A plurality of hard macros may be disposed in the macro-region HMR.

According to an embodiment of the present inventive concept, the first pitch P1 in the second region N may be greater than the first distance w1 in the first region O.

According to an embodiment of the present inventive concept, the second pitch P2 in the second region N may be smaller than the second distance w2 in the first region O.

According to an embodiment of the present inventive concept, the first pitch P1 may be greater than a pitch BP between the connection bumps 123 (see FIG. 4).

According to an embodiment of the present inventive concept, as the macro-region HMR is disposed between the through silicon vias 125 disposed in the first direction D1, the empty region WSR, in which the hard macro is not disposed, may be decreased. Accordingly, the chip size of the semiconductor device may be reduced, and the manufacturing yield of the semiconductor device may be increased.

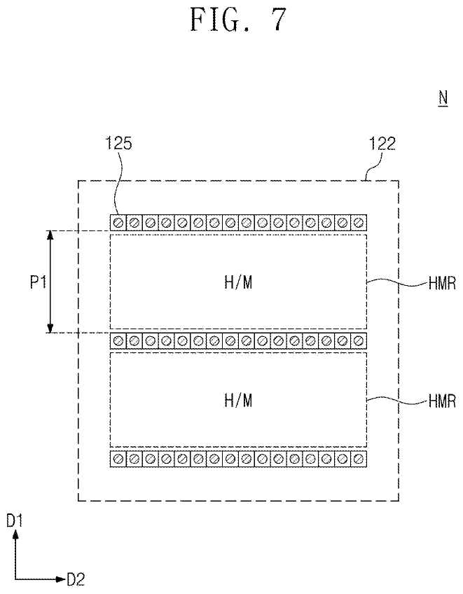

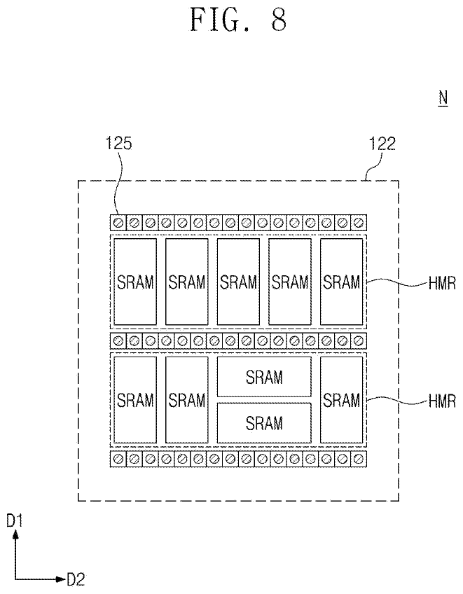

FIG. 7 is a view illustrating a second region of FIG. 5 according to an embodiment of the present inventive concept. FIG. 8 is a view illustrating a state in which SRAM is disposed in the macro-region of FIG. 7.

Referring to FIG. 7, the through silicon vias 125 arranged in the second direction D2 may be adjacent to each other, which differs from FIG. 6. In the specification, the through silicon vias 125 adjacent to each other may refer to that the through silicon vias 125 are arranged at a minimum distance such that the through silicon vias 125 are not electrically shorted to each other.

Referring to FIG. 8, the plurality of hard macros may be disposed in the macro-region HMR. For example, a plurality of SRAMs may be disposed in the macro-region HMR. The SRAMs may have the same shape as each other and may be disposed vertically to be parallel to the first direction D1 or horizontally to be parallel to the second direction D2. However, the present inventive concept is not limited thereto, and different hard macros having different sizes from each other may be arranged in the macro-region HMR.

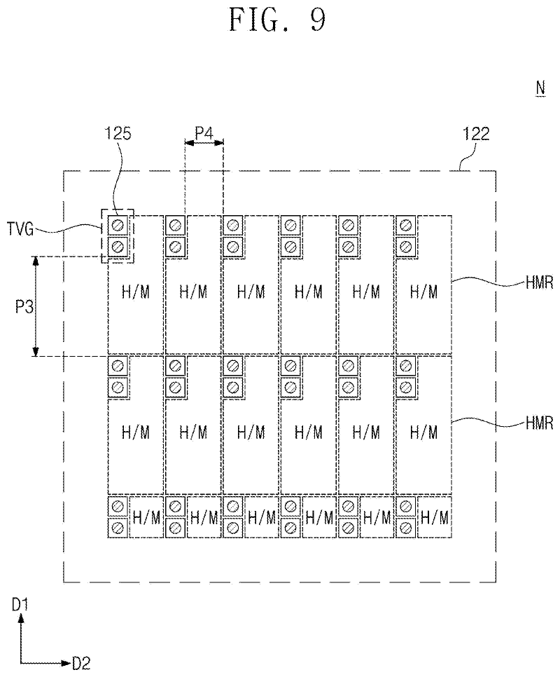

FIG. 9 is a view illustrating a second region of FIG. 5 according to an embodiment of the present inventive concept.

Referring to FIG. 9, according to an embodiment of the present inventive concept, the plurality of through silicon via groups TVG and macro-regions HMR may be disposed in the second region N of the first die 120.

Each of through silicon via groups TVG may include a plurality of through silicon vias 125 arranged in the first direction D1. A plurality of through silicon vias 125 included in the through silicon via groups TVG may be disposed adjacent to each other in the first direction D1. For example, one through silicon via group TVG may include two adjacent through silicon vias 125. However, the present inventive concept is not limited to FIG. 5, and the through silicon via group TVG may include at least two through silicon vias 125.

The through silicon via groups TVG may be spaced apart from each other in the first direction D1. For example, the through silicon via groups TVG may be disposed at regular (e.g., predetermined) intervals in the first direction D1. For example, the minimum distance between the through silicon via groups TVGs in the first direction D1 may be the third pitch P3. The third pitch P3 may be about 150 μm to about 200 μm.

The through silicon vias 125 may be spaced apart from each other in the second direction D2. For example, the through silicon via groups TVG may be disposed at regular intervals in the second direction D2. For example, the minimum distance between the through silicon vias 125 in the second direction D2 may be a fourth pitch P4. The fourth pitch P4 may be in the range of about 100 μm to about 150 μm.

According to an embodiment of the present inventive concept, the third pitch P3 may be smaller than the first pitch P1 in FIG. 6. Accordingly, a voltage drop phenomenon in the first direction D1 of power supplied from the second die 130 may be further alleviated.

A portion of the macro-region HMR may be interposed between the through silicon via groups TVGs that are spaced apart from each other in the first direction D1. For example, a portion of the macro-region HMR may be interposed between the through silicon via groups TVGs in the first direction D1. A portion of the macro-region HMR may also be interposed between the through silicon via groups TVGs arranged in the second direction D2. For example, a portion of the macro-region HMR may be interposed between the through silicon via groups TVGs in the second direction D2. The plurality of hard macros may be disposed in the macro-region HMR.

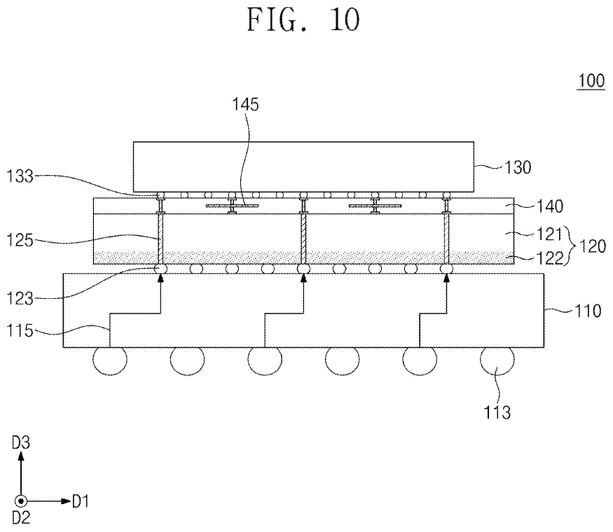

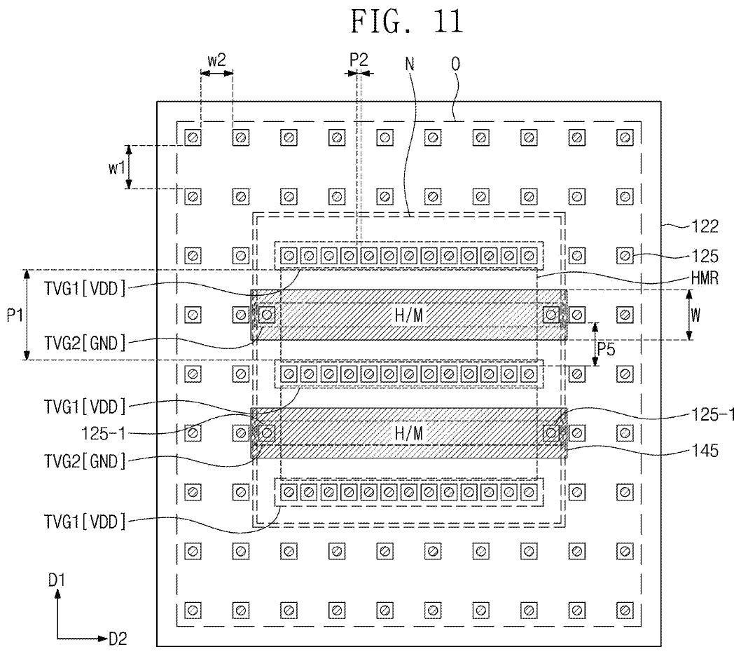

FIG. 10 is a view illustrating a semiconductor device according to an embodiment of the present inventive concept. FIG. 11 is a plan view illustrating a first die of FIG. 10. Hereinafter, the following description will be made while focusing on the difference from the description made with reference to FIGS. 4 to 6, and the description substantially the same as those described in FIGS. 4 to 6 will may be omitted or briefly discussed.

Referring to FIGS. 10 and 11, according to an embodiment of the present inventive concept, the package substrate 110, the first die 120, the second die 130, and a rear wire layer 140 may be provided. The package substrate 110 and the second die 130 may be substantially the same as those of FIG. 4.

The active layer 122 of the first die 120 may include the first region O in which the hard macro is not disposed and the second region N in which the hard macro is disposed.

The plurality of through silicon vias 125 may be disposed in the first region O of the first die 120. In the first region O, the through silicon vias 125 may be arranged in the first direction D1 and the second direction D2.

The through silicon vias 125 may be spaced apart from each other by a specific distance. In the first region O, the closest through silicon vias 125 in the first direction D1 may be spaced apart from each other by the first distance w1. In the first region O, the closest through silicon vias 125 in the second direction D2 may be spaced apart from each other by a second distance w2.

A plurality of through silicon vias 125 and the macro-regions HMR may be disposed in the second region N of the first die 120.

In the second region N, the through silicon via 125 that are adjacent to the macro-regions HMR may be divided into the first through silicon via groups TVG1 and the second through silicon via groups TVG2. The first through silicon via groups TVG1 may include through silicon vias 125 configured to supply a power supply voltage VDD to the second die 130. The second through silicon via groups TVG2 may include ground through silicon vias 125-1 configured to supply a ground voltage GND to the second die 130.

The first through silicon via groups TVG1 may be spaced apart from each other in the first direction D1. For example, the distance between the first through silicon via groups TVG1 may be the first pitch P1, as illustrated in FIG. 6. For example, the first pitch P1 may be in the range of about 100 μm to about 200 μm.

Each of the first through silicon via groups TVG1 may include a plurality of through silicon vias 125 arranged in the second direction D2. According to an embodiment of the present inventive concept, the through silicon vias 125 included in the first through silicon via groups TVG1 may be disposed at regular intervals in the second direction D2. For example, the distance between the through silicon vias 125 of the first through silicon via groups TVG in the second direction D2 may be the second pitch P2, as illustrated in FIG. 6. The second pitch P2 may be about 1 μm to about 10 μm. According to an embodiment of the present inventive concept, as illustrated in FIG. 7, the through silicon vias 125 of the first through silicon via group TVG1 may be adjacent to each other. For example, the through silicon vias 125 of the first through silicon via group TVG1 may be in contact with each other.

Macro-regions HMR may be interposed between first through silicon via groups TVG1 spaced apart from each other in the first direction D1. The macro-regions HMR may extend in the second direction D2 to be adjacent to the first through silicon via groups TVG1.

The second through silicon via groups TVG2 may be spaced apart from each other in the first direction D1. The second through silicon via group TVG2 may be alternately disposed with the first through silicon via groups TVG1. The second through silicon via group TVG2 may be spaced apart from the first through silicon via group TVG1 by a fifth pitch P5 in the first direction D1. For example, the fifth pitch P5 may be about 10 μm to about 100 μm.

Each of the second through silicon via groups TVG2 may include a pair of ground through silicon vias 125-1 spaced apart from each other in the second direction D2. The macro-region HMR may be disposed between the pair of ground through silicon vias 125-1. For example, each ground through silicon via 125-1 of the pair of ground through silicon vias 125-1 may be disposed to be spaced apart from the macro-region HMR.

The first rear wire layer 140 may be interposed between the first die 120 and the second die 130 (see FIG. 10). The first rear wire layer 140 may include first connection vias and first ground wires 145. The first connection vias may electrically connect the through silicon via 125, which passes through the first die 120, to the micro-bumps 133 of the second die 130.

First ground wires 145 may be provided on the macro-regions HMR. For example, the first ground wires 145 may extend in the second direction D2 on the macro-region HMR. For example, at least a portion of the first ground wires 145 may be overlapped with the macro-region HMR in a vertical direction (e.g., the third direction D3).

The first ground wire 145 may be connected in common with the ground through silicon vias 125-1 of the second through silicon via group TVG2. For example, a pair of ground through silicon vias 125-1 may be electrically connected to opposite ends of the first ground wire 145. In other words, the pair of ground-through silicon vias 125-1 may be electrically shorted through the first ground wire 145.

According to an embodiment of the present inventive concept, the stability and reliability of the ground voltage provided to the second die 130 through the ground through silicon vias 125-1 may be increased.

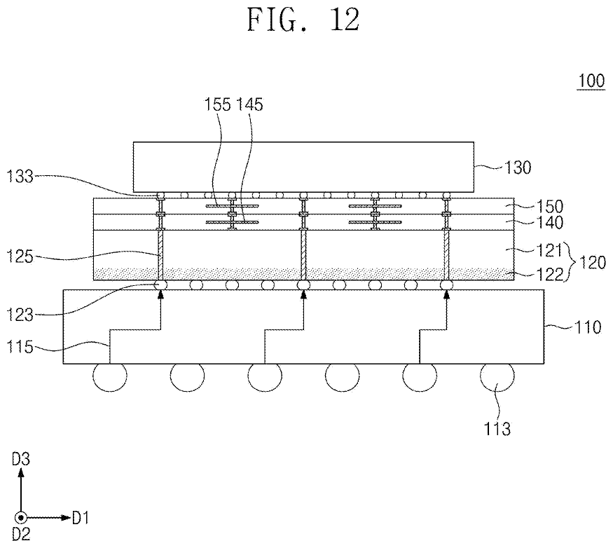

FIG. 12 is a view illustrating a semiconductor device according to an embodiment of the present inventive concept. Hereinafter, the following description will be made while focusing on the difference from the description made with reference to FIGS. 10 to 11, and the description substantially the same as those described in FIGS. 10 to 11 may be omitted or briefly discussed.

Referring to FIG. 12, according to an embodiment of the present inventive concept, the package substrate 110, the first die 120, the second die 130, the first rear wire layer 140, and the second rear wire layer 150 may be provided. The package substrate 110, the first die 120, the second die 130, and the first rear wire layer 150 may be substantially the same as those illustrated in FIG. 4.

A second rear wire layer 150 may be interposed between the first rear wire layer 140 and the second die 130. The second rear wire layer 150 may include second connection vias and second ground wires 155. The second connection vias may be electrically connected to the first connection vias of the first rear wire layer 140 and the micro-bumps 133 of the second die 130.

Second ground wires 155 may be provided on the macro-regions HMR. The second ground wires 155 may be provided on the first ground wires 145. For example, the second ground wires 155 may be connected to the first ground wires 145. For example, the second ground wires 155 may extend in the second direction D2 on the macro-region HMR. For example, at least a portion of the second ground wire 155 may be overlapped with the macro-region HMR in the vertical direction (e.g., the third direction D3).

The second ground wire 155 may be connected in common with a pair of ground through silicon vias 125-1 of the second through silicon via group TVG2. For example, ground through silicon vias 125-1 may be electrically connected to opposite ends of the second ground wire 155.

As described above, according to an embodiment of the present inventive concept, the semiconductor device with an improved electrical characteristic may be provided.

According to an embodiment of the present inventive concept, the semiconductor device capable of being produced with increased manufacturing yield may be provided.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A semiconductor device comprising:
a package substrate;
a first die provided on the package substrate and including a hard macro and a plurality of through silicon vias; and
a second die provided on the first die and electrically connected to the plurality of through silicon vias,
wherein the first die includes a first region, in which the hard macro is not disposed, and a second region including a macro-region in which the hard macro is disposed,
wherein the plurality of through silicon vias of the first region are arranged in a first direction with a first distance therebetween and in a second direction with a second distance therebetween, wherein the second direction crosses the first direction,
wherein the plurality of through silicon vias of the second region are arranged in the first direction with a first pitch, and in the second direction with a second pitch,
wherein the macro-region is interposed between the plurality of through silicon vias that are arranged in the first direction in the second region,
wherein the first pitch is greater than the first distance, and
wherein the second pitch is less than the second distance.

2. The semiconductor device of claim 1, wherein the first pitch is in a range of about 100 μm to about 200 μm.

3. The semiconductor device of claim 2, wherein the second pitch is in a range of about 1 μm to about 10 μm.

4. The semiconductor device of claim 1, further comprising:
connection bumps interposed between the package substrate and the first die, wherein the first pitch is greater than a pitch between the connection bumps.

5. The semiconductor device of claim 4, wherein the connection bumps are C4 bumps.

6. The semiconductor device of claim 1, wherein the macro-region extends in the second direction.

7. The semiconductor device of claim 6, wherein the plurality of through silicon vias of the second region are arranged along a first lateral side of the macro-region and a second lateral side that is opposite to the first lateral side.

8. The semiconductor device of claim 1, wherein the first die includes a central processing unit (CPU), a graphic processing unit (GPU), or a system on chip (SoC).

9. The semiconductor device of claim 8, wherein the second die includes a central processing unit (CPU), a graphic processing unit (GPU), or a system on chip (SoC).

10. The semiconductor device of claim 1, wherein the hard macro includes a static random access memory (SRMA).

11. A semiconductor device comprising:
a package substrate;
a first die provided on the package substrate and including a hard macro and a plurality of through silicon vias; and
a second die provided on the first die and electrically connected to the plurality of through silicon vias,
wherein the first die includes a first region, in which the hard macro is not disposed, a second region including a macro-region, in which the hard macro is disposed, and through silicon via groups including the plurality of through silicon vias,
wherein the plurality of through silicon vias of the first region are arranged in a first direction with a first distance therebetween, and in a second direction with a second distance therebetween, wherein the second direction crosses the first direction,
wherein the through silicon via groups are arranged to be spaced apart from each other in the first direction and the second direction in the second region,
wherein the macro-region is interposed between the through silicon via groups in the first direction and between the through silicon via groups in the second direction, and
wherein each of the through silicon via groups includes a first plurality of through silicon vias, of the plurality of through silicon vias, arranged in the first direction.

12. The semiconductor device of claim 11, wherein a minimum distance between the through silicon via groups in the first direction is a third pitch, and
wherein the third pitch is in a range of about 150 μm to about 200 μm.

13. The semiconductor device of claim 12, wherein a minimum distance between the through silicon via groups in the second direction is a fourth pitch, and
wherein the fourth pitch is in a range of about 100 μm to about 150 μm.

14. The semiconductor device of claim 11, wherein the first plurality of through silicon vias of each of the through silicon via groups are adjacent to each other.

15. The semiconductor device of claim 11, wherein the first die includes a central processing unit (CPU), a graphic processing unit (GPU), or a system on chip (SoC).

16. The semiconductor device of claim 15, wherein the second die includes a central processing unit (CPU), a graphic processing unit (GPU), or a system on chip (SoC).

17. The semiconductor device of claim 11, wherein the hard macro includes a static random access memory (SRMA).

18. A semiconductor device comprising:
a package substrate;
a first die provided on the package substrate and including a substrate and an active layer;
a rear wire layer provided on the first die and including a ground wire; and
a second die provided on the rear wire layer,
wherein the active layer includes first through silicon via groups, second through silicon via groups, and a macro-region, wherein the first through silicon via groups include through silicon vias configured to supply a power supply voltage to the second die, wherein the second through silicon via groups include ground through silicon vias configured to supply a ground voltage to the second die, and wherein a hard macro is disposed in the macro-region,
wherein the macro-region is interposed between the first through silicon via groups, and
wherein the ground wire is electrically connected to the ground through silicon vias.

19. The semiconductor device of claim 18, wherein at least a portion of the ground wire is vertically overlapped with the macro-region.

20. The semiconductor device of claim 18, wherein the first through silicon via groups and the second through silicon via groups are alternately disposed.
